(19) United States
(12) Patent Application Publication
(10) Pub. No.: US 2023/0395537 A1
(43) Pub. Date: Dec. 7, 2023

(54) BUMP OF CHIP PACKAGE WITH HIGHER BEARING CAPACITY IN WIRE BONDING

(71) Applicant: WALTON ADVANCED ENGINEERING, INC., Kaohsiung (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/206,591

(22) Filed: Jun. 6, 2023

(30) Foreign Application Priority Data
Jun. 7, 2022 (TW) 111121072

(51) Int. Cl. H01L 23/00

(52) U.S. Cl. CPC H01L 24/05; H01L 24/04; H01L 24/48; H01L 2224/04042; H01L 2224/05082; H01L 2224/05155; H01L 2224/05083; H01L 2224/05164; H01L 2224/05008; H01L 2224/02373; H01L 2224/02375; H01L 2224/05644; H01L 2224/48091; H01L 2224/48105; H01L 2224/48464; H01L 2224/05026; H01L 2224/05571; H01L 2224/05541

(57) ABSTRACT

A bump of a chip package with higher bearing capacity in wire bonding is provided. The at least one bump of the chip package is a metal stacked member with a certain thickness. An overall thickness of the bump is 4.5-20 μm. Thereby a structural strength of the bump is improved and thus able to bear positive pressure generated in wire bonding or formation of a first bonding point. Thus at least one internal circuit of a chip will not be damaged by the positive pressure and allowed to pass through an area under at least one die pad or arrange under the die pad of the chip. Thereby increased cost problem caused by internal circuit redesign of the chip can be solved and this helps to reduce cost at manufacturing end.

### CROSS-REFERENCE TO RELATED APPLICATIONS

This non-provisional application claims priority under 35 U.S.C. § 119(a) on Patent Application No(s). 111121072 filed in Taiwan, R.O.C. on Jun. 7, 2022, the entire contents of which are hereby incorporated by reference.

### BACKGROUND OF THE INVENTION

The present invention relates to a bump of a chip package, especially to a bump of a chip package with higher bearing capacity in wire bonding.

In the field of chip packaging, electrical connection between a chip package and an electronic component is achieved by wire bonding. By a bonding wire which is used to form a bonding point on respective bumps of the chip package and another bonding point on the electronic component, the chip package and the electronic component are electrically connected. However, while performing wire bonding, the chip package available now may be unable to stand a positive pressure from the wire bonding or generated during formation of the bonding point so that internal circuit of the chip is damaged by the positive pressure. Thus the internal circuit is not easy or unable to pass through an area under respective die pads or arrange under the respective die pads of the chip package. Thereby manufacturers need to redesign the internal circuit of the chip and this leads to an increased cost at manufacturing end.

Thus there is room for improvement and there is an urgent need to provide a novel bump of a chip package able to solve the problem of difficulty in arrangement of the internal circuit of the chip at the manufacturing end.

### SUMMARY OF THE INVENTION

Therefore, it is a primary object of the present invention to provide at least one bump of a chip package with higher bearing capacity in wire bonding in which the bump of the chip package is a metal stacked member with a certain thickness. The overall thickness of the bump is set to 4.5-20 μm. Thus structural strength of the respective bumps is enhanced and able to stand a positive pressure generated in wire bonding or formation of a first bonding point. Thereby at least one internal circuit of a chip will not be damaged by the positive pressure. And the internal circuit is allowed to pass through an area under at least one die pad or arrange under the die pad of the chip. Therefore, an issue of increased cost caused by internal circuit redesign of the chip at the manufacturing end can be addressed.

In order to achieve the above object, at least one bump of a chip package with higher bearing capacity in wire bonding according to the present invention is provided. The chip package includes a chip, at least one dielectric layer, and at least one bump. The chip consists of a first surface and at least one internal circuit. The first surface is provided with at least one die pad and at least one protective layer. The chip is formed by cutting of a wafer. The first surface of the chip is covered by the dielectric layer correspondingly while the dielectric layer is provided at least one opening which is corresponding to a position of the die pad. The bump is mounted in the opening of the dielectric layer, facing upwards and exposed.

The bump is a stacked layered member electrically connected with a top surface of the die pad of the chip. While performing wire bonding, a first bonding point and a second bonding point are respectively formed on the bump and an electronic component by a bonding wire for electrical connection between the chip package and the electronic component. The chip package features on that the bump is a metal stacked member with a certain thickness and composed of a nickel (Ni) layer and a gold (Au) layer stacked from the top surface of the die pad in turn. An overall thickness of the bump is set within a range of 4.5 to 20 μm. Thus structural strength of the respective bumps is enhanced and able to bear a positive pressure generated in wire bonding or formation of the first bonding point. Thereby the internal circuit of the chip will not be damaged by the positive pressure and allowed to pass through a part of the chip under the die pad, or arranged under the die pad. This helps manufacturers to reduce cost.

Preferably, a thickness of the gold (Au) layer in the bump is 0.005-0.2 μm while the rest of the thickness of the bump is a thickness of the nickel (Ni) layer.

In order to achieve the above object, at least one bump of a chip package with higher bearing capacity in wire bonding according to the present invention is provided. The chip package includes a chip, at least one dielectric layer, and at least one bump. The chip consists of a first surface and at least one internal circuit. At least one die pad and at least one protective layer are disposed on the first surface. The chip is formed by cutting of a wafer. The first surface of the chip is covered by the dielectric layer correspondingly while the dielectric layer is provided at least one opening which is corresponding to a position of the die pad. The bump is mounted in the opening of the dielectric layer, facing upwards and exposed. The bump is a stacked layered member electrically connected with a top surface of the die pad of the chip. While performing wire bonding, a first bonding point and a second bonding point are respectively formed on the bump and an electronic component by a bonding wire for electrical connection between the chip package and the electronic component. The chip package features on that the bump is a metal stacked member with a certain thickness and composed of a nickel (Ni) layer, a palladium (Pd) layer, and a gold (Au) layer stacked from the top surface of the die pad in turn. An overall thickness of the respective bumps is set within a range of 4.5 to 20 μm. Thus structural strength of the respective bumps is enhanced and able to bear a positive pressure generated in wire bonding or formation of the first bonding point. Thereby the internal circuit of the chip will not be damaged by the positive pressure and being allowed to pass through the die pad, or arranged under the die pad. This is beneficial to cost reduction at the manufacturing end.

Preferably, a thickness of the gold (Au) layer and a thickness of the palladium (Pd) layer in the bump are respectively 0.005-0.2 μm and 0.005˜0.3 μm while the rest of the thickness of the bump is a thickness of the nickel (Ni) layer.

### BRIEF DESCRIPTION OF THE DRAWINGS

FIG. 1 is a side view of a section of a first embodiment according to the present invention;

FIG. 2 is a schematic drawing showing a side view of a section of a chip of the first embodiment being cut from a wafer according to the present invention;

FIG. 3 is a side view of a section of a second embodiment according to the present invention;

FIG. 4 is a schematic drawing showing a side view of a section of a chip of the second embodiment being cut from a wafer according to the present invention;

FIG. 5 is a sectional view showing chip packaging of the first embodiment according to the present invention;

FIG. 6 is a sectional view showing chip packaging of the second embodiment according to the present invention;

FIG. 7 is a partial enlarged view of the embodiment in FIG. 5 according to the present invention;

FIG. 8 is a partial enlarged view of the embodiment in FIG. 6 according to the present invention;

FIG. 9 is a schematic drawing showing a top plan view of internal circuit of an embodiment according to the present invention;

FIG. 10 is a schematic drawing showing a top plan view of chip packaging of an embodiment according to the present invention.

### DETAILED DESCRIPTION OF THE PREFERRED EMBODIMENT

A structure and technical features of the present invention are described in details in the following embodiments with reference to related figures and reference signs. The size of the respective components shown in figure is not drawn to scale and not intended to limit the present invention.

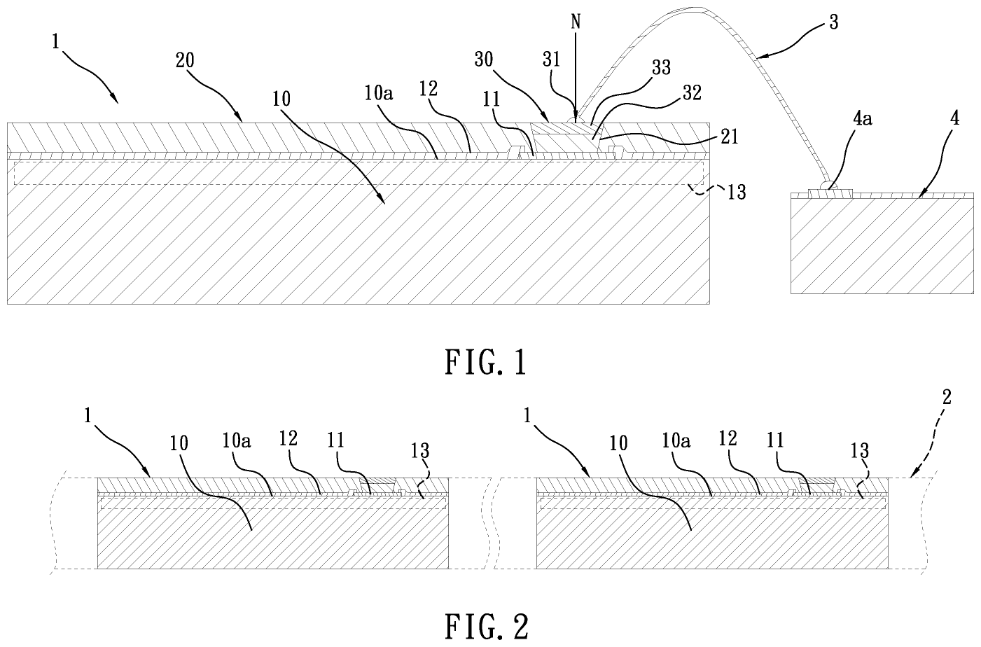

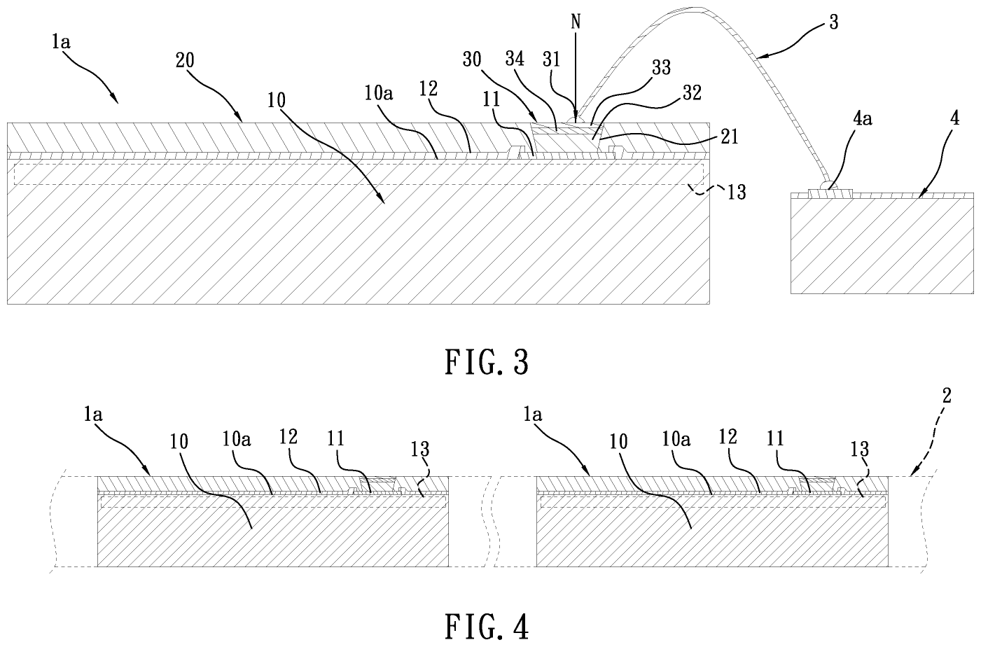

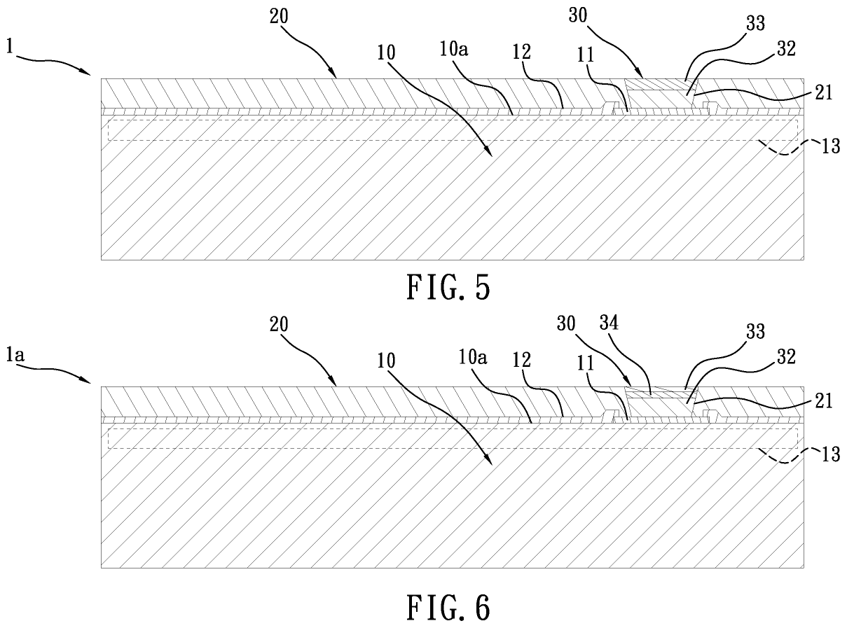

Refer to FIG. 1, FIG. 3, FIG. 5, and FIG. 6, a bump of a chip package with higher bearing capacity in wire bonding is provided. A chip package 1, la includes a chip 10, at least one dielectric layer 20, and at least one bump 30. The chip 10 consists of a first surface 10a and at least one internal circuit 13. The first surface 10a is provided with at least one die pad 11 and at least one protective layer 12. The chip 10 is formed by cutting of a wafer 2 (as shown in FIG. 2 and FIG. 4). The first surface 10a of the chip 10 is covered by the dielectric layer 20 correspondingly while the dielectric layer is provided at least one opening 21 which is corresponding to a position of the die pad 11. The bump 30 is mounted in the opening 21 of the dielectric layer 20, facing upwards and exposed. The bump 30 is a stacked layered member electrically connected with a top surface of the die pad 11 of the chip 10. While performing wire bonding, as shown in FIG. 1 and FIG. 3, a first bonding point 31 and a second bonding point 4a are respectively formed on the bump 30 and an electronic component 4 by a bonding wire 3 for electrical connection between the chip package 1, la and the electronic component 4.

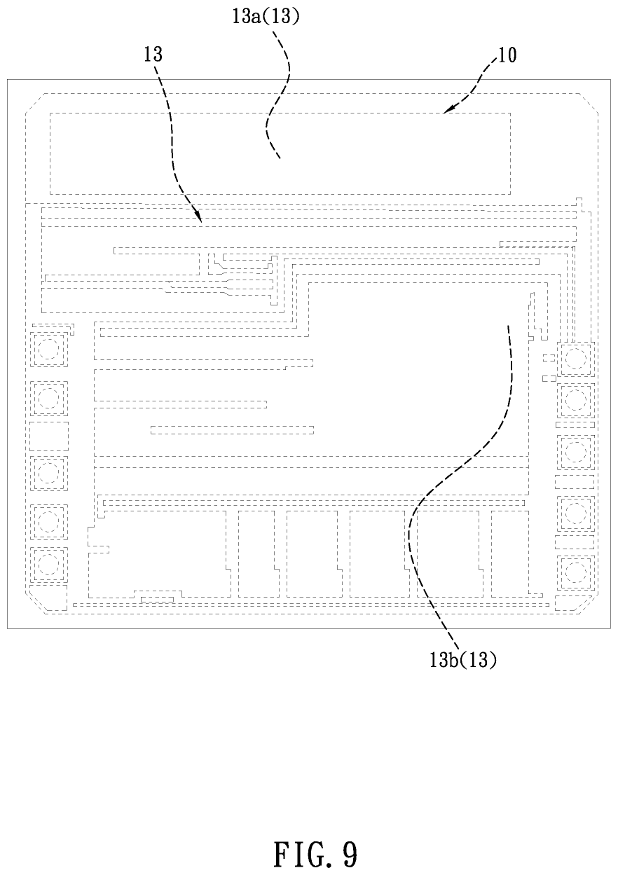

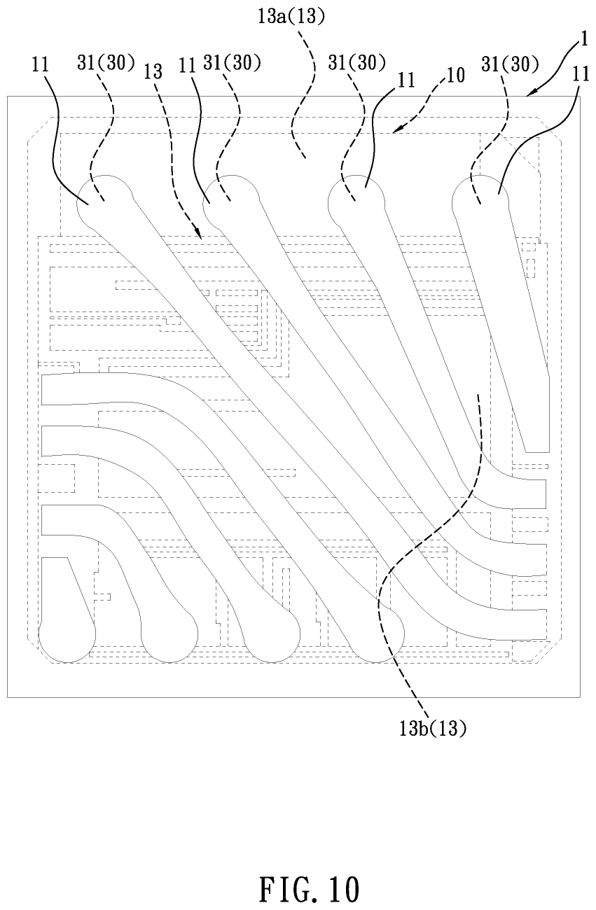

As shown in FIG. 9 and FIG. 10, the internal circuit 13 includes an array area 13a and a circuitry area 13b (or cell) not shown in the figures), but not limited.

According to different materials and composition of the stacked layered member of the bump 30, please refer to the following first embodiment (the chip package 1) and second embodiment (the chip package 1a), as shown in FIG. 1 and FIG. 3. The structure or technical features of the chips 10 and the dielectric layers 20 in the first embodiment (the chip package 1) are the same as those in the second embodiment (the chip package 1a).

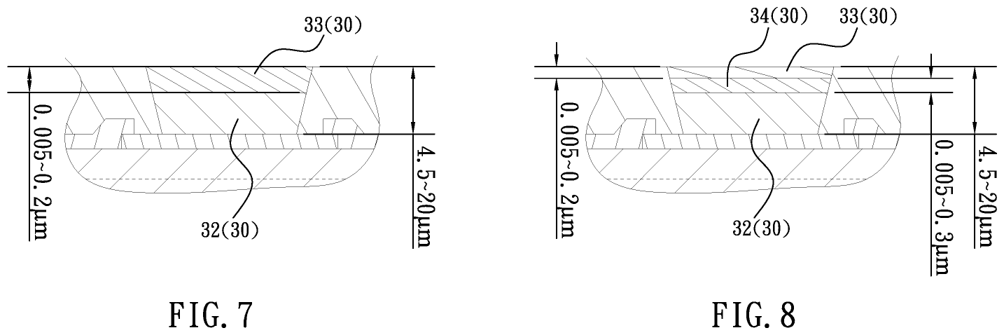

Refer to the chip package 1 of the first embodiment shown in FIG. 1, FIG. 2, FIG. 5, and FIG. 7, the bump 30 is a metal stacked member with a certain thickness and composed of a nickel (Ni) layer 32 and a gold (Au) layer 33 stacked from the top surface of the die pad 11 in turn, as shown in FIG. 1 and FIG. 5. An overall thickness of the respective bumps 30 is set within a range of 4.5 to 20 micrometers (μm), as shown in FIG. 7. Thus structural strength of the respective bumps 30 is enhanced and able to bear a positive pressure N generated in wire bonding or formation of the first bonding point 31, as shown in FIG. 1. Thereby the internal circuit 13 of the chip 10 will not be damaged by the positive pressure N (as shown in FIG. 1). Therefore, the internal circuit 13 is allowed to pass through an area under the die pad 11, or arranged under the die pad 11, as shown in FIG. 1 and FIG. 10.

As shown in FIG. 7, a thickness of the gold (Au) layer 33 in the bump 30 is 0.005-0.2 μm, but not limited while the rest of the thickness of the bump 30 is a thickness of the nickel (Ni) layer 32. The distribution ratio mentioned above can reduce the amount of the gold (Au) layer 33 having higher cost and used in the bump 30 while without losing a certain amount of structural strength. The above design helps to reduce cost at the manufacturing end.

Refer to the chip package 1a of the second embodiment shown in FIG. 3, FIG. 4, FIG. 6, and FIG. 8, the bump 30 is a metal stacked member with a certain thickness and composed of a nickel (Ni) layer 32, a palladium (Pd) layer 34, and a gold (Au) layer 33 stacked from the top surface of the die pad 11 in turn, as shown in FIG. 3 and FIG. 6. An overall thickness of the respective bumps 30 is set within a range of 4.5 to 20 micrometers (μm), as shown in FIG. 8. Thus structural strength of the respective bumps 30 is enhanced and able to bear a positive pressure N generated in wire bonding or formation of the first bonding point 31, as shown in FIG. 3. Thereby the internal circuit 13 of the chip 10 will not be damaged by the positive pressure N (as shown in FIG. 3). The internal circuit 13 is allowed to pass through an area under the die pad 11, or arranged under the die pad 11, as shown in FIG. 3 and FIG. 10.

As shown in FIG. 8, a thickness of the gold (Au) layer 33 and a thickness of the palladium (Pd) layer 34 in the bump 30 are respectively 0.005-0.2 μm and 0.005-0.3 μm, but not limited while the rest of the thickness of the bump 30 is a thickness of the nickel (Ni) layer 32. The distribution ratio mentioned above can reduce the amount of the gold (Au) layer 33 having higher cost and used in the bump 30 while without losing a certain amount of structural strength. The above design is beneficial to cost reduction at the manufacturing end.

Compared with the chip package available now, the present invention has the following advantages.

The bump 30 of the chip package 1 of the first embodiment according to the present invention is a metal stacked member composed of the nickel (Ni) layer 32 and the gold (Au) layer 33, as shown in FIG. 1, FIG. 2, FIG. 5, and FIG. 7 while the bump 30 of the chip package 1a of the second embodiment according to the present invention is a metal stacked member composed of the nickel (Ni) layer 32, the palladium (Pd) layer 34, and the gold (Au) layer 33, as shown in FIG. 3, FIG. 4, FIG. 6, and FIG. 8. The overall thickness of the bump 30 is set to be within 4.5-20 μm, as shown in FIG. 7 and FIG. 8. Thus the structural strength of the respective bumps 30 is improved in order to bear the positive pressure N generated in wire bonding or formation of the first bonding point 31, as shown in FIG. 1 and FIG. 3. Thereby the internal circuit 13 of the chip 10 will not be damaged by the positive pressure N (as shown in FIG. 1 and FIG. 3). The internal circuit 13 is allowed to pass through an area under the die pad 11, or arranged under the die pad 11, as shown in FIG. 10. Therefore, an issue of increased cost caused by internal circuit redesign of the chip at the manufacturing end can be addressed and such design helps to reduce cost at the manufacturing end.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A bump of a chip package with higher bearing capacity in wire bonding comprising the chip package having a chip, at least one dielectric layer, and at least one the bump; wherein the chip includes at least one internal circuit and a first surface which is provided with at least one die pad and at least one protective layer; wherein the chip is formed by cutting of a wafer; wherein the first surface of the chip is covered by the dielectric layer correspondingly while the dielectric layer is provided at least one opening which is corresponding to the die pad of the chip; wherein the bump is mounted in the opening of the dielectric layer, facing upwards and exposed; the bump is a stacked layered member electrically connected with a top surface of the die pad of the chip; wherein while performing the wire bonding, a first bonding point and a second bonding point are respectively formed on the bump and an electronic component by a bonding wire for electrical connection between the chip package and the electronic component; wherein the bump is a metal stacked member with a thickness and including a nickel (Ni) layer and a gold (Au) layer stacked from the top surface of the die pad in turn; wherein the thickness of the bump is set to 4.5-20 μm; thus structural strength of the bump is enhanced and able to bear a positive pressure generated in the wire bonding or formation of the first bonding point; thereby the internal circuit of the chip will not be damaged by the positive pressure and being allowed to pass through an area under the die pad, or arranged under the die pad.

2. The bump of the chip package as claimed in claim 1, wherein a thickness of the gold (Au) layer in the bump is 0.005-0.2 μm and the rest of the thickness of the bump is a thickness of the nickel (Ni) layer.

3. A bump of a chip package with higher bearing capacity in wire bonding comprising the chip package having a chip, at least one dielectric layer, and at least one the bump; wherein the chip includes at least one internal circuit and a first surface which is provided with at least one die pad and at least one protective layer; wherein the chip is formed by cutting of a wafer; wherein the first surface of the chip is covered by the dielectric layer correspondingly while the dielectric layer is provided at least one opening which is corresponding to the die pad of the chip; wherein the bump is mounted in the opening of the dielectric layer, facing upwards and exposed; the bump is a stacked layered member electrically connected with a top surface of the die pad of the chip; wherein while performing the wire bonding, a first bonding point and a second bonding point are respectively formed on the bump and an electronic component by a bonding wire for electrical connection between the chip package and the electronic component; wherein the bump is a metal stacked member with a thickness and including a nickel (Ni) layer, a palladium (Pd) layer, and a gold (Au) layer stacked upward from the top surface of the die pad in turn; wherein the thickness of the bump is set to 4.5-20 μm; thus structural strength of the bump is enhanced and able to stand a positive pressure generated in the wire bonding or formation of the first bonding point; thereby the internal circuit of the chip will not be damaged by the positive pressure and being allowed to pass through an area under the die pad, or arranged under the die pad.

4. The bump of the chip package as claimed in claim 3, wherein a thickness of the gold (Au) layer 33 and a thickness of the palladium (Pd) layer 34 in the bump 30 are respectively 0.005-0.2 μm and 0.005˜0.3 μm and the rest of the thickness of the bump is a thickness of the nickel (Ni) layer.
